(19) United States
(12) Patent Application Publication
(10) Pub. No.: US 2005/0047607 A1
(43) Pub. Date: Mar. 3, 2005

(54) System and method for sharing acoustical signal control among acoustical virtual environments

(76) Inventor: Ronald R. Freiheit, Owatonna, MN (US)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(21) Appl. No.: 10/934,650

(22) Filed: Sep. 3, 2004

Related U.S. Application Data
(60) Provisional application No. 60/499,770, filed on Sep. 3, 2003.

(51) Int. Cl. H03G 3/00; H02B 1/00

(52) U.S. Cl. 381/61; 381/123

(57) ABSTRACT

A system for sharing acoustical signal control among acoustical virtual environments generally includes a number of acoustic performance modules, a single acoustical system, and a switchable, single control system. The switchable single control system is interfaced to each of the acoustic performance modules and is operably connected to the single acoustical system. The control system is switchable to one of the acoustic performance modules whereby acoustic signals are able to flow between the performance module and the acoustical system; acoustic signals between all other performance modules and the acoustic system are blocked.

### CLAIM TO PRIORITY

The present application claims priority to U.S. Provisional Patent Application No. 60/499,770, filed Sep. 3, 2003 and entitled “ENHANCED VIRTUAL ACOUSTIC PRACTICE ROOM.” The identified provisional patent application is hereby incorporated by reference.

### FIELD OF THE INVENTION

The present invention relates to acoustical virtual environments and, more specifically, relates to the ability to utilize a single acoustical signal control system to produce a desired acoustical environment in each one of a selected plurality of a closed acoustical environment.

### BACKGROUND OF THE INVENTION

Musicians and speech givers spend many hours rehearsing their pieces. In the past, this practice occurred in small acoustically isolated rehearsal areas which allowed the performer the opportunity to hear themselves clearly. In conventional rehearsal rooms, the rehearsal room is constructed of sound blocking materials to isolate the rehearsal area from the external sounds of the surrounding areas. Within the room, reverberations of the sounds generated by the performer are frequently absorbed by the room walls, floor and/or ceiling to prevent the reverberations of the performance from overwhelming the performer.

In contrast to a small rehearsal room, the reverberations of a performance hall or auditorium echo through the larger space of the performance hall creating a very different acoustical environment. A performance hall typically includes space dedicated to holding an audience while a conventional rehearsal room does not. It is the differences in the direction of the reverberations, sound intensity and time lag of the reverberations through the differing volumes of physical space which create the acoustical environment of a room. For the performer, the difference in the acoustical environments between a small rehearsal room and large performance hall can hinder performances.

Frequently, the performer does not have access to the performance hall or may not have access for a sufficient amount of time to become accustomed to the acoustical environment of the performance hall. In conventional rehearsal rooms, the dimensions and construction materials of the room cannot be easily changed to alter the acoustical environment to simulate a performance environment.

With the advent of electronics, electroacoustic systems using microphones, speakers and other electronic devices can enhance the acoustical environment of large performance halls to solve acoustical problems, such as inadequate reverberation time or level, insufficient lateral energy or excessive time delay, stemming from the basic problems of speaker placement, microphone placement, and acoustic feedback in the large hall. Unfortunately, many of these systems are expensive, use complex designs that are not easily changed or incorporated in small rehearsal rooms and may require a dedicated operator to use.

In addition, these systems are not readily adaptable to placement in a small physical area such as a rehearsal or practice room because they are not designed to compensate for the strong sound coloration and acoustic feedback in a small enclosed space. In a small enclosed space, sound waves bounce off the walls and swirl back on themselves even as new sound waves are produced. It is difficult to isolate and capture the desired sound waves from the reverberating waves in a small enclosed space.

Home entertainment systems which try to simulate the listening environment of a larger auditorium in a home encounter the same problems of sound coloration and acoustic feedback as well as the problem of distinguishable echoes emanating from individual speakers as the listener moves around the room.

A rehearsal room which provides an acoustically isolated practice area and is readily adaptable to simulate a variety of acoustical environments during a performance would be greatly appreciated and has been provided by Wenger Corporation. Such a rehearsal room is described in U.S. Pat. No. 5,525,765, the contents of which is incorporated herein by reference. What is more desirable yet is the ability to utilize a single acoustical signal control system to produce a desired acoustical environment in each one of a selected plurality of a closed acoustical environments.

### SUMMARY OF THE INVENTION

The needs described above are in large part met by a system for sharing acoustical signal control among acoustical virtual environments of the present invention. The system generally includes a number of acoustic performance modules, a single acoustical system, and a switchable, single control system. The switchable single control system is interfaced to each of the acoustic performance modules and is operably connected to the single acoustical system. The control system is switchable to one of the acoustic performance modules whereby acoustic signals are able to flow between the performance module and the acoustical system; acoustic signals between all other performance modules and the acoustic system are blocked.

The control system is able to adjust to a correct acoustic signal calibration level according to the size of the selected performance module. The signal flow between the performance module and single acoustical system produces a desired acoustical environment, e.g., a performance venue that is selectable from Arena, Baroque, Cathedral, Small Auditorium, Medium Auditorium, Large Auditorium, Medium Recital Hall, and Large Recital Hall.

A method for sharing acoustical signal control among acoustical virtual environments, includes the steps of: (1) switchably interfacing a single acoustical system to acoustic performance modules; (2) selecting a first acoustic performance module from among the acoustic performance modules; (3) switching the single acoustical system to communicate only with the first acoustic performance module; (4) simulating a desired acoustical environment within the first acoustic performance module through use of the single acoustical system and the acoustical elements within the first acoustic performance module; (5) selecting a second acoustic performance module from among the acoustic performance modules; (6) switching the single acoustical system to communicate only with the second acoustic performance module; and (7) simulating a desired acoustical environment within the second acoustic performance module through use of the single acoustical system and the acoustical elements within the second acoustic performance module.

### BRIEF DESCRIPTION OF THE DRAWINGS

FIG. 1 is a perspective view of the acoustic performance module in accordance with the present invention;

FIG. 2 is a rear perspective view of the acoustic performance module;

FIG. 3 is a top plan view of the acoustic performance module with the ceiling removed for clarity;

FIG. 4 is an elevational view of the inner surface of side walls of the acoustic performance module;

FIG. 5 is an elevational view of inner surface of front wall of the acoustic performance module;

FIG. 6 is an elevational view of the inner surface of the rear wall of the acoustic performance module;

FIG. 7 is a bottom plan view of the inside top wall (the ceiling) of the acoustic performance module;

FIG. 8 is a schematic diagram of the electroacoustic system in accordance with the present invention;

FIG. 9 is an elevational view of the inner surface of side walls of the acoustic performance module in accordance with an alternate embodiment;

FIG. 10 is an elevational view of inner surface of front wall of the acoustic performance module in accordance with an alternate embodiment;

FIG. 11 is an elevational view of the inner surface of the rear wall of the acoustic performance module in accordance with an alternate embodiment; and

FIG. 12 is a diagram illustrating how the electronics of single acoustic performance module can be shared with one or more additional acoustic performance modules.

### DETAILED DESCRIPTION OF THE PREFERRED EMBODIMENTS

Referring now to the drawings, wherein like reference numerals denote like elements throughout the several views, an acoustic performance module 10, as illustrated in FIGS. 1, 2 and 3, broadly includes a performing space 12 defined by front wall 14, opposed side walls 16, 18, rear wall 20, floor 22 and ceiling 24, and electroacoustic system 26.

Each of walls 14, 16, 18, 20 carries an upper wall margin 28, lower wall margin 30, opposed side margins 31, inner surface 32 and outer surface 34. Each of the walls 14, 16, 18, 20 presents a characteristic height of at least seven and a half feet.

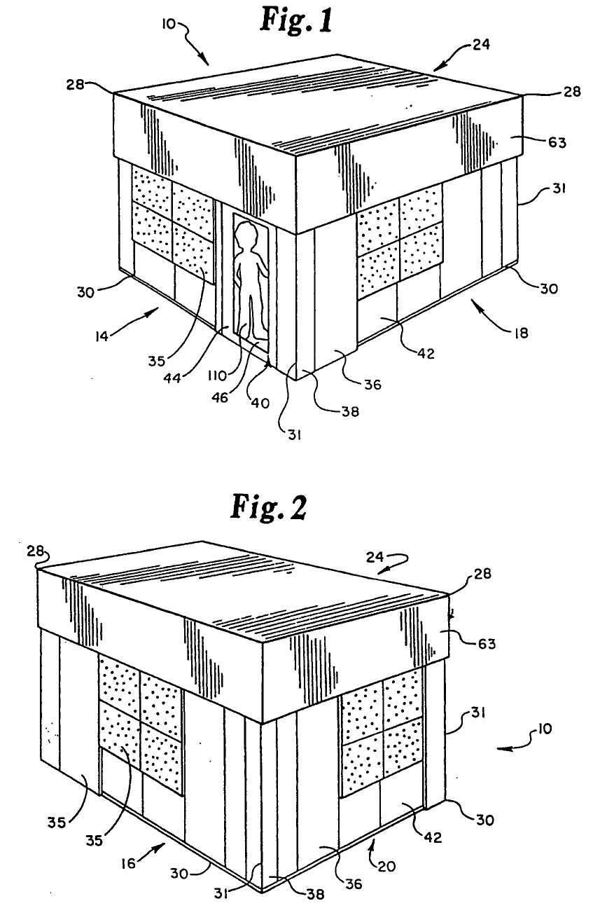

Referring to FIGS. 1 and 2, the outer surface 34 of each of the walls 14, 16, 18, 20 may include one or more facades 35. The facades 35 may vary in construction and material and provide an aesthetically pleasing look to the outer surface 34 of the walls 14, 16, 18, 20.

The inner surface 32 of each of the walls 14, 16, 18, 20 includes a plurality of vertical modular panels 36, 38, 40, 42 of substantially uniform height but which may vary in width and construction. For example, modular panel 38 presents relatively narrow characteristic width in comparison to modular panel 36. Modular panel 40 includes a swinging door 44 with glass panel 46. Modular panel 42 includes perforated inner liners 48 housing one or more sound absorption panels 50.

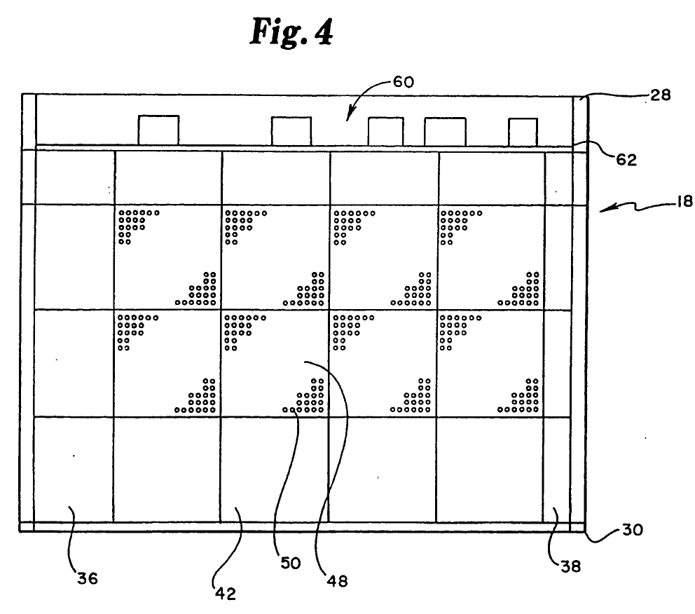

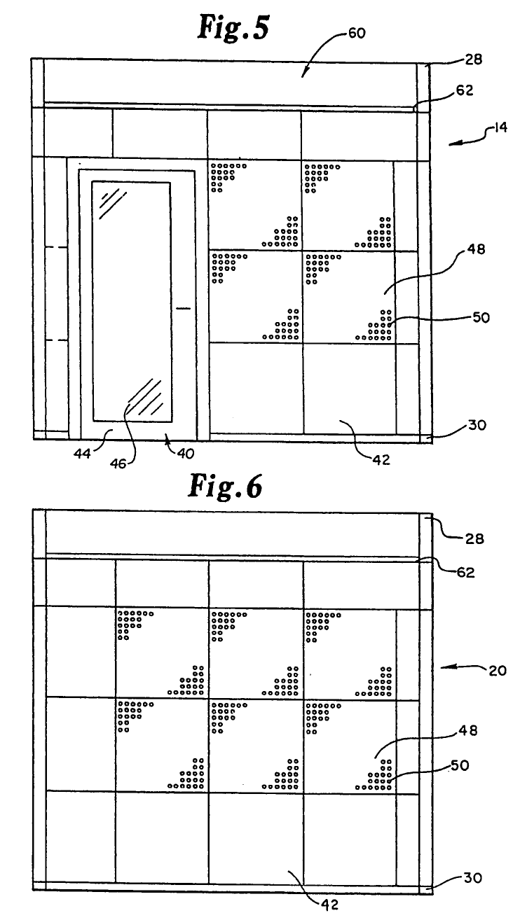

Referring to FIGS. 4-6, each of the inner surfaces 32 of each of walls 14, 16, 18, 20 includes a plurality of sound absorption panels 50 protected by inner liners 48 mounted on one or more modular panels 42. The absorption panels 50 are made of material with anechoic characteristics, such as, for example, absorption panels of the model no. 2540000 series manufactured by Wenger Corporation of Owatonna, Minn.

The floor 22 is generally horizontal and extends along and between the lower wall margins 30 of the walls 14, 16, 18, 20. The floor is of sufficient size to accommodate several chairs or individuals. The floor 22 may be constructed of various nonporous materials. In the preferred embodiment, the floor 22 is constructed of wood.

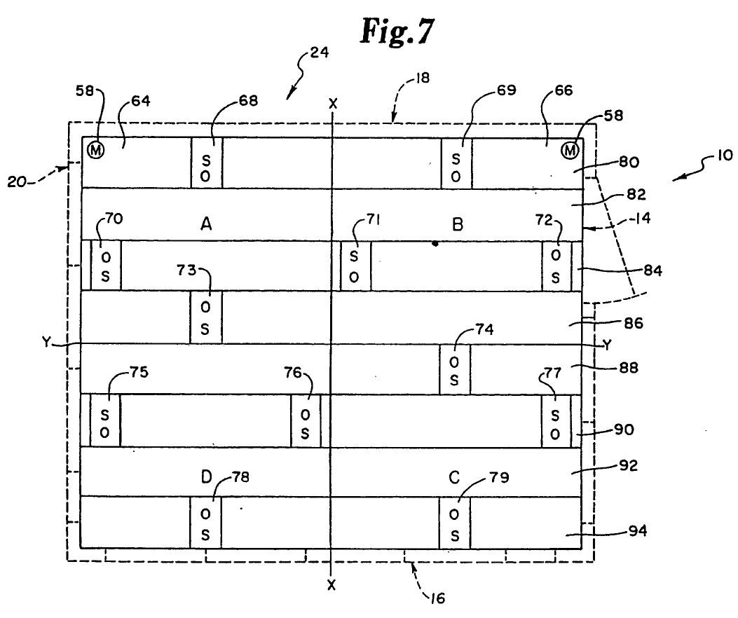

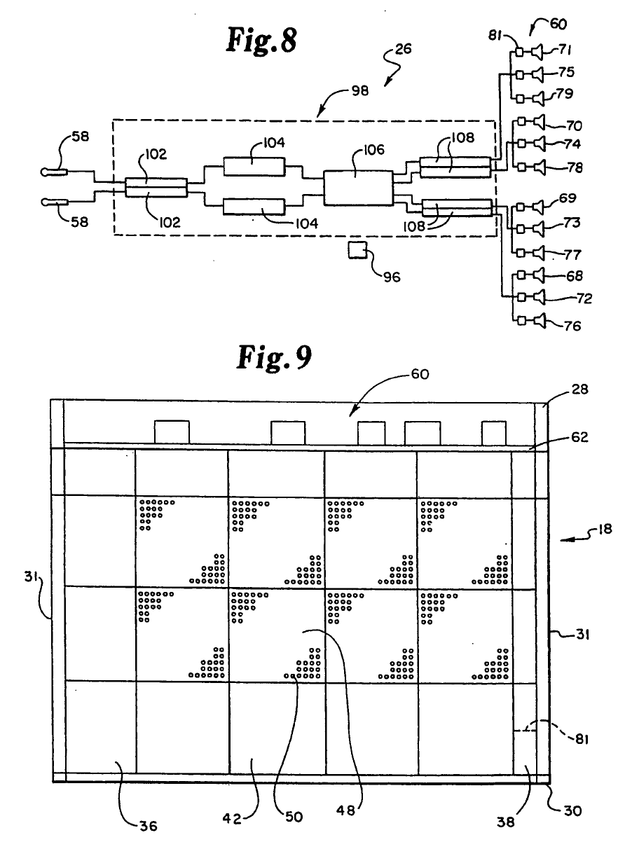

Referring to FIG. 7, the ceiling 24 extends along and between the upper wall margins 28 of the walls 14, 16, 18, 20 (shown in shadow). In the preferred embodiment, the ceiling 24 broadly includes a plurality of microphones 58, a speaker array 60, an inner ceiling 62, an outer shield 63, a right inner corner 64 and left inner corner 66. Referring to FIGS. 9-11, in an alternate embodiment, at least a portion of the speaker array 60 is positioned in one or more walls 14, 16, 18, 20 and one or more microphones 58 are positioned in one or more walls 14, 20.

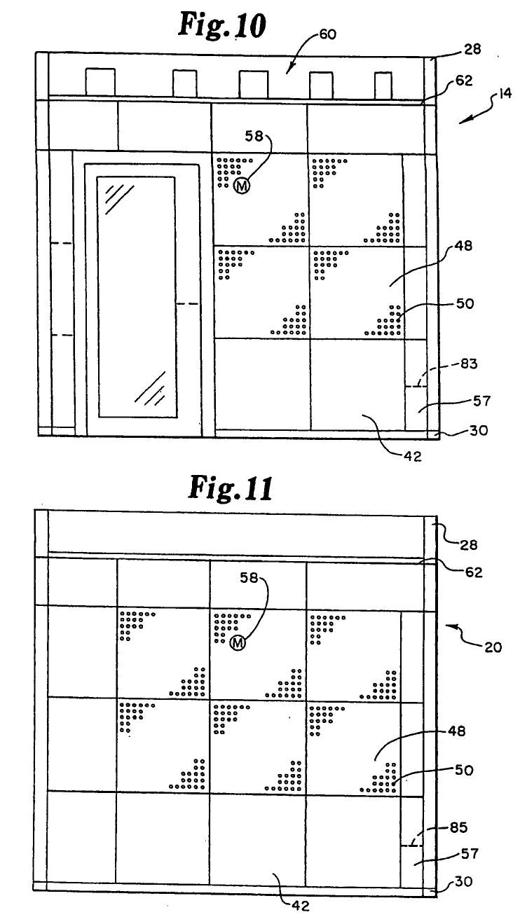

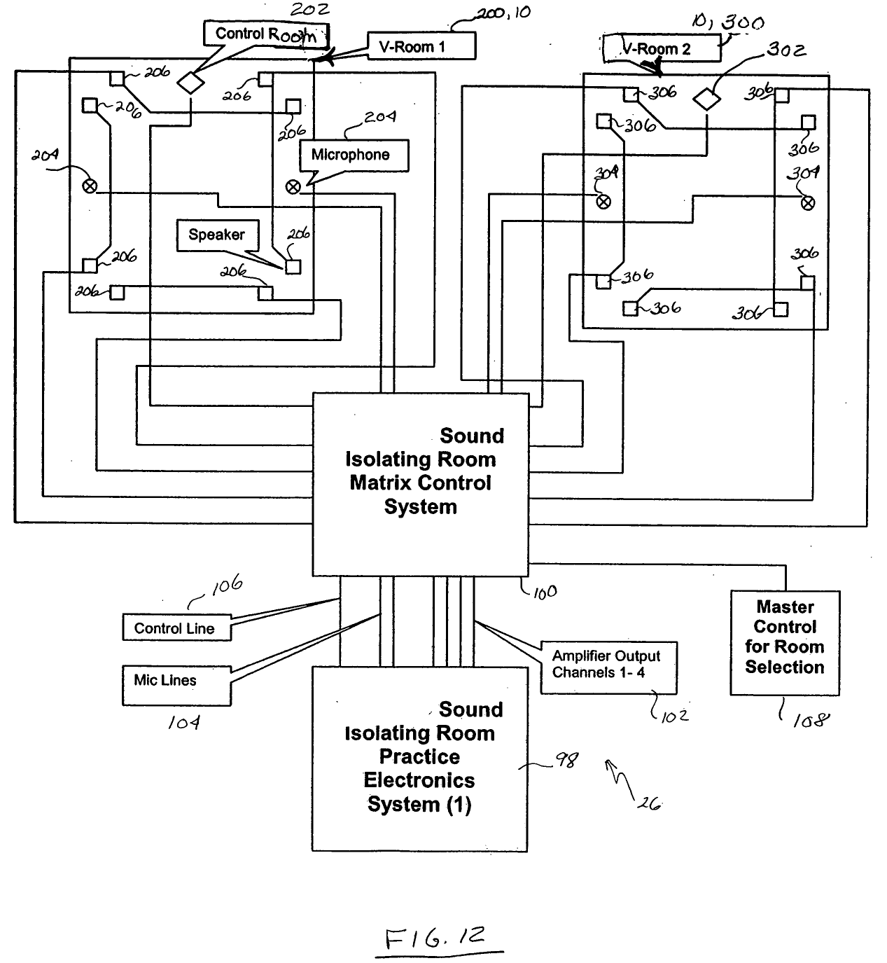

The microphones 58 are mounted against the ceiling 24 an equidistance from the center of the performing space 12 and are positioned relative to a predetermined pattern of the speaker array 60. In the preferred embodiment, the microphones 58 are adjacent to the right inner corner 64 and left inner corner 66 of the ceiling 24. Referring to FIGS. 10 and 11, in an alternate embodiment, each of the microphones 58 are positioned in opposed walls 14, 18 at least 5 feet from the lower wall margin 30 and equidistant from opposed side margins 31. More specifically, each microphone 58 is mounted 72″ from the lower wall margin 30. In the alternate embodiment, the microphones 58 are at least 3 feet from any one of the speakers in the speaker array 60. Each of the microphones 58 are directed into the performance space 12 and positioned at least eighteen inches from any possible source of sound within the performing space 12. In the alternate embodiment, each of the microphones are directed to the floor 22. The microphones are of a flat frequency response type with low self noise, such as, for example, SM102 series microphones of SHURE.

The speaker array 60 includes a plurality of speakers 68, 69, 70, 71, 72, 73, 74, 75, 76, 77, 78, 79 mounted against the ceiling 24 in a predetermined pattern and aligned with each other speaker 68, 69, 70, 71, 72, 73, 74, 75, 76, 77, 78, 79 along the same medial plane. In an alternate embodiment, the speaker array 60 includes a plurality of speakers 68, 69, 70, 71, 72, 73, 74, 75, 76, 77, 78, 79, 81, 83, 85, 87 for a total of sixteen speakers in speaker array 60. Speakers 68, 69, 70, 71, 72, 73, 74, 75, 76, 77, 78, 79 are mounted against the ceiling 24 in a predetermined pattern and aligned with each other speaker 68, 69, 70, 71, 72, 73, 74, 75, 76, 77, 78, 79 along the same medial plane.

Referring to FIGS. 9-11, in an alternate embodiment, speakers 81, 83, 85, 87 are mounted adjacent to the lower wall margins 30 of the walls 14, 16, 18, 20. More specifically, each of the speakers 81, 83, 85, 87 are recessed into a wall 14 at the corners of the room, i.e., adjacent to lower wall margins 30 and side margins 31 of two adjacent walls 14, 16, 18, 20.

The speakers 68, 69, 70, 71, 72, 73, 74, 75, 76, 77, 78, 79, 81, 83, 85, 87 may possess similar or different properties. In the preferred embodiment, the speakers 68, 69, 70, 71, 72, 73, 74, 75, 76, 77, 78, 79, 81, 83, 85, 87 are of similar make and construction and provide performance levels of ±2 dB from 70 Hz-20 kHz (on axis 0°) and ±2 dB from 70 Hz-15 kHz (off axis 30°). Each of the speakers includes a transformer 81 operably attached to the speaker 68, 69, 70, 71, 72, 73, 74, 75, 76, 77, 78, 79, 81, 83, 85, 87.

The speaker array 60 pattern is predetermined to provide even sound coverage of the performance space 12 and reduce sound distortions occurring when the ear distinguishes the sounds of one speaker 68 from those of another 69. Those skilled in the art will recognize that other speaker arrays 60 are possible.

In the preferred embodiment, the speaker array 60 includes three speakers positioned in each of four zones A, B, C, D. For purposes of discussion, the ceiling 24 is divided into eight generally parallel channels 80, 82, 84, 86, 88, 90, 92, 94 and four zones. The zones are labeled A, B, C and D beginning in the left inner corner 66 and moving clockwise around the ceiling 24. Each channel 80 extends between side walls 16, 18.

The speaker positions in zones A and C are mirror images of each other along vertical plane along line X-X and the speaker positions in zones B and D are mirror images of each other along line Y-Y.

More specifically, in the preferred embodiment, in zone A, speakers 68, 73 are placed equidistant from side wall 20 and vertical plane X-X in channels 80, 86 and speaker 70 is positioned adjacent to side wall 20 in channel 84. In zone B, a speaker 69 is placed equidistant from side wall 14 and vertical plane X-X in channel 80. In channel 84 in zone B speakers 71, 72 are placed adjacent to side wall 14 and adjacent to vertical plane X-X. In zone C, speakers 74, 79 are placed equidistant from side wall 14 and vertical plane X-X in channels 88, 94. Speaker 77 is placed adjacent to side wall 14 in channel 90. In zone D, speaker 78 is placed equidistant from side wall 20 and vertical plane X-X in channel 94. In channel 90 in zone D speakers 75, 76 are placed adjacent to side wall 20 and adjacent to vertical plane X-X.

In addition, each of the speakers 68, 69, 70, 71, 72, 73, 74, 75, 76, 77, 78, 79 are positioned such that each speaker is connected to the electroacoustic system 26 via a different channel than adjacent speakers. For example, referring to FIG. 7, speakers 68, 72, 76 are connected to the electroacoustic system 26 through the same channel; speakers 69, 73, 77 are connected to the electroacoustic system 26 through the same channel but a different channel than that which connects speakers 68, 72, 76 to the electroacoustic system 26. Speakers 70, 74, 78 are connected to the electroacoustic system 26 through a third channel and speakers 71, 75, 79 are connected to the electroacoustic system 26 through a fourth channel. In the alternate embodiments, each of the four speakers 81, 83, 85, 87 is connected to the electroacoustic system 26 through a different channel than the other speakers 81, 83, 85, 87.

The inner ceiling 62 extends along and between the walls 14, 16, 18, 20 adjacent to the speakers 68. The inner ceiling is formed of perforated metal. The outer shield 63 is secured to the ceiling 24 and extends downwardly along at least a portion of the walls 14, 16, 18, 20.

The walls 14, 16, 18, 20, floor 22 and ceiling 24 are secured together to form a rigid box-like structure. It is understood that the width and length of the performing space 12 defined by the walls 14, 16, 18, 20, floor 22 and ceiling 24 may vary according to whether the rehearsal room is designed to accommodate individual performers, an ensemble or larger performing groups such as a band. It will be understood that an increase in the length and width of the performing space 12 will require a corresponding increase in the number of speakers in the speaker array 60.

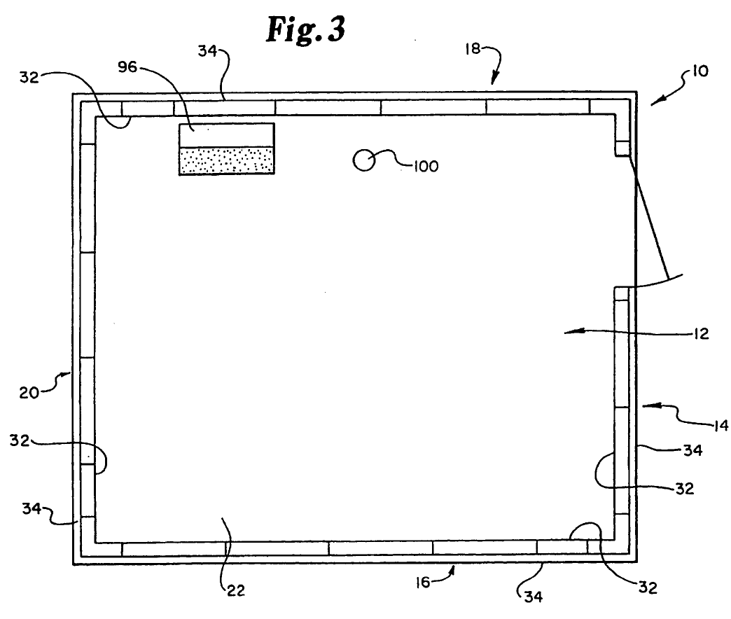

Referring to FIGS. 3 and 8, the electroacoustic system 26 broadly includes remote user input device 96 and computer-based acoustical control system 98. The remote user input device 96 is mounted within the performance space 12 and operably connected to the acoustical control system 98. It will be understood that the user input device 96 may be, for example, a computer keyboard and monitor, a series of dials, buttons, levers or a computer touchscreen. In an alternate embodiment, the user input device 96 may be a MIDI control device, such as, for example, MRC panel by Lexicon of Waltham, Mass., which is connected to the acoustical control system 98 through a port connection 100 in the floor 22 (shown in FIG. 3).

As shown in FIG. 8, the acoustical control system 98 is operably attached to the microphones 58 and speaker array 60 but located at a location remote from the performing space 12. The acoustical control system 98 includes a plurality of microphone pre-amplifiers 102, a plurality of twenty eight band graphic equalizers 104, a digital sound processor 106 and a plurality of amplifiers 108. The microphone pre-amplifiers 102 are preferably operated with a low signal to noise ratio and are transformer coupled, such as Model MP-2 manufactured by Gaines Audio. The equalizers 104 perform within ±2 dB signal to noise ratio with balanced input and outputs, such as, for example, Model MPE28 manufactured by Rane Corporation of Mukilteo, Wash. The sound processor 106 is a system, such as the LARES system sold by Lexicon of Waltham, Mass., which is capable of providing time-variant synthetic reverberation of sound with at least 4 channels output and controlled via RS-422 remote selection or MIDI. The amplifiers 108 preferably have a low signal to noise ratio with a minimum of 50 watts per channel at 8 ohms. Those skilled in the art will recognize that the acoustical control system 98 may include sound recording equipment for permanent storage of performances.

In operation, a performer 110 enters the performance space 12 and selects the type of acoustical environment desired by entering user selected data into the user input device 96. It is understood that the performer may be an individual or a group of persons. The performer 110 then begins to produce sound, such as, for example, by speaking or playing a musical instrument. The sound waves produced move out from the performer into the performance space 12. As the sound waves contact the sound absorption panels 50, the sound is absorbed and little or no reverberation is produced. The placement of the sound absorption panels 50 along the walls 14, 16, 18, 20 of the performance space 12 produces a semi-anechoic environment.

As the sound waves travel toward the ceiling 24, walls 14, 16, 18, 20 and floor 22 the sound is captured by the microphones 58, channeled through the electroacoustic system 26 and then broadcast to the performer 110 through speaker array 60.

As those skilled in the art understand, in the alternate embodiment, placement of the microphones 58 in opposed walls 14, 20 offers a logarithmic gain in sound with the increased distance from the speakers 68, 69, 70, 71, 72, 73, 74, 75, 76, 77, 78, 79, 81, 83, 85, 87. Thus, the captured sound can be broadcast back to the performer at higher decibel levels such that the room sounds louder. Greater control of the volume of the sound maximizes the ability to mimic smaller, more intimate performance halls with greater accuracy.

The predetermined pattern of the speaker array 60 and the placement of the speakers 68, 69, 70, 71, 72, 73, 74, 75, 76, 77, 78, 79 in the same medial plane well above the head of the performer 110 minimizes the ability of the performer's ears to distinguish the exact origin of the sound. In an alternate embodiment of the predetermined pattern of the speaker array 60, the placement of the speakers 68, 69, 70, 71, 72, 73, 74, 75, 76, 77, 78, 79, 81, 83, 85, 87 in both the walls 14, 16, 18, 20 and against the ceiling 24 enhances the sound of the room by surrounding the performer more completely with sound. To the performer's ear, the alternate embodiment minimizes the decay of sound traveling from the speakers 68, 69, 70, 71, 72, 73, 74, 75, 76, 77, 78, 79 mounted against the ceiling by providing sound from speakers 81, 83, 85, 87. The broadcast sound blends clearly. The alternate embodiment minimizes the problem of having all the sound originate from above the performer as if the performer was performing in a well. The speaker array 60 provides even sound coverage of the room regardless of the exact position of the performer within the performing space 12.

In order to provide a variety of acoustical environments, the electroacoustic system 26 alters the sound wave to simulate the direction of reverberations, sound intensity and time lag of reverberations that would be produced if the sound wave was echoing in a large concert hall or auditorium. The sound absorption panels 50 help simulate the anechoic nature of large performance halls provided by the audience space. Because of the placement and arrangement of the speaker array 60, the auralization effect simulates the acoustical environment of a large performance hall though the performer 110 is actually in a small enclosed rehearsal room. The performer 110 hears the performance as it would sound in the large performance hall.

It will be understood that by changing the simulated sound, parts of the room may give the auralization effect of performing on a more enclosed stage in a large performance hall while the remainder of the room may simulate the unencumbered audience portion of the performance hall. Further, it will be understood that by changing the simulated sound the auralization effect can be adjusted to simulate numerous performance venues including, but not limited to: Arena; Baroque; Cathedral; Small Auditorium; Medium Auditorium; Large Auditorium; Medium Recital Hall; Large Recital Hall.

The inner ceiling 62 secures the speakers 68, 69, 70, 71, 72, 73, 74, 75, 76, 77, 78, 79 from theft and provides a uniform visual surface. The outer shield 63 provides additional protection to the electroacoustic system and enhances the sound isolation of the room from external noises. In an alternate embodiment, panels 57 protect speakers 81, 83, 85, 87 from theft while permitting sound to broadcast from the speakers 81, 83, 85, 87. Location of the acoustical system 98 in a secure location from the performing space 12 allows for increased security of the equipment and operation of the rehearsal room with a rehearsal room operation in attendance.

FIG. 12 depicts a system for sharing the acoustical system 98 among a plurality of acoustic performance modules 10. While FIG. 12 depicts only two acoustic performance modules 10, i.e., practice room 200 and practice room 300, by way of example, it should be understood that the acoustical system 98 can be used with more than two acoustic performance modules through use of the matrix control system 100.

The system of FIG. 12 allows a single acoustical system 98 electronics package to be shared between a number of practice rooms that are equipped with microphones, e.g., 204 and 304, with speakers, e.g., 206 and 306, and a control panel found in control room 202, 302. The system utilizes a matrix control system 100 that enables the functionality of acoustical system 98 to be switched between practice rooms, 200 and 300. A master control for room selection 108 is provided and enables a user to select a desired practice room with which the user wishes to use the acoustical system 98. The selection of the desired practice room is transferred from the master control 108 to the matrix control system 100. The matrix control system 108 utilizes a plurality of switches to control routing of the various signals, e.g., the amplifier outputs (channels 1-4) 102, Mic lines 104, and control line 106, to the desired practice room. The switching system within the matrix control system 100 preferably includes an automatic adjustment for correct calibration level depending on the room selected, i.e., smaller rooms attenuate signals at a different level than larger rooms, such that a consistent environment is maintained when a user is moving from practice room to practice room. In other words, the matrix control system 100 is operable with a plurality of practice rooms regardless or the practice room size. In a preferred embodiment the matrix control system 100 is a stand-alone unit that can be integrated with any new or existing acoustical system.

Numerous characteristics and advantages of the invention have been set forth in the foregoing description. It will be understood, of course, that this disclosure is, in many respects, only illustrative. Changes can be made in details, particularly in the matters of shape, size and arrangement of parts without exceeding the scope of the invention. The invention scope is defined by the language by which the appended claims are expressed.

1. A system for sharing acoustical signal control among acoustical virtual environments, comprising:
a plurality of acoustic performance modules;
a switchable, single control system interfaced to each of said plurality of performance modules; and
a single acoustical system operably connected to said single control system,
wherein upon switching said single control system to a particular one of said plurality of acoustic performance modules, only said single acoustical system and said particular one of said plurality of acoustic performance modules are able to transfer acoustic signals to produce a desired acoustical environment.

2. The system of claim 1, wherein said single control system adjusts to a correct acoustic signal calibration level according to the particular acoustic module to which said control system is switched.

3. The system of claim 1, wherein said single control system adjusts to a correct acoustic signal calibration level according to the size of the particular acoustic module to which said control system is switched.

4. The system of claim 1, wherein said desired acoustical environment is selectable from a plurality of simulated performance venues.

5. The system of claim 4, wherein said plurality of simulated performance venues include: Arena, Baroque, Cathedral, Small Auditorium, Medium Auditorium, Large Auditorium, Medium Recital Hall, and Large Recital Hall.

6. The system of claim 1, wherein each of said acoustic performance modules includes a microphone, a speaker, and a control panel.

7. A method for sharing acoustical signal control among acoustical virtual environments, comprising the steps of:
switchably interfacing a single acoustical system to a plurality of acoustic performance modules;
selecting a first acoustic performance module from among said plurality of acoustic performance modules;
switching said single acoustical system to communicate only with the first acoustic performance module;
simulating a desired acoustical environment within the first acoustic performance module through use of said single acoustical system and a plurality of acoustical elements within the first acoustic performance module;
selecting a second acoustic performance module from among said plurality of acoustic performance modules;
switching said single acoustical system to communicate only with the second acoustic performance module; and
simulating a desired acoustical environment within the second acoustic performance module through use of said single acoustical system and a plurality of acoustical elements within the second acoustic performance module.

8. The method of claim 7, further including the step of adjusting to a correct acoustic signal calibration level according to the acoustic performance module that is selected.

9. The method of claim 7, further including the step of adjusting to a correct acoustic signal calibration level according to the acoustic performance module that is selected.

10. The method of claim 7, further comprising the step of selecting said desired acoustical environment from a plurality of simulated performance venues.

11. The method of claim 10, wherein said plurality of simulated performance venues include: Arena, Baroque, Cathedral, Small Auditorium, Medium Auditorium, Large Auditorium, Medium Recital Hall, and Large Recital Hall.

12. The method of claim 7, wherein said plurality of acoustical elements includes a microphone, a speaker, and a control panel.

13. A system for sharing acoustical signal control among acoustical environments, comprising:
plurality of performance means, each for providing an enclosed acoustical environment;
single simulation means for acoustically simulating a desired performance venue within a single performance means;
single switching means for selecting one of said plurality of performance means and for enabling acoustic signal communication between only the selected performance means and said single simulation means to produce the simulation of said desired performance venue within the selected performance means.

14. The system of claim 13, wherein said single switching means for adjusting to a correct acoustic signal calibration level within said performance means dependent on the performance means selected.

15. The system of claim 13, wherein said single switching means for adjusting to a correct acoustic signal calibration level within said performance means dependent upon the size of the performance means selected.

16. The system of claim 13, wherein the simulated desired performance venue is selectable from the following venues: Arena, Baroque, Cathedral, Small Auditorium, Medium Auditorium, Large Auditorium, Medium Recital Hall, and Large Recital Hall.

17. The system of claim 13, wherein said performance means includes a plurality of acoustic elements including a microphone, a speaker and a control panel.
